(19) United States
(12) Patent Application Publication
(10) Pub. No.: US 2016/0211191 A1
(43) Pub. Date: Jul. 21, 2016

(54) HEAT SINK ASSEMBLY WITH FRAME CLIP FOR FULLY ASSEMBLED ATTACHMENT TO HEAT GENERATING COMPONENT

(71) Applicant: Aavid Thermalloy, LLC, Laconia, NH (US)

(72) Inventors: RUI SHENG TAN, Shanghai (CN); Sukhvinder S. Kang, Concord, NH (US)

(73) Assignee: Aavid Thermalloy, LLC, Laconia, NH (US)

(21) Appl. No.: 15/083,474

(22) Filed: Mar. 29, 2016

Related U.S. Application Data
(63) Continuation of application No. PCT/CN2013/084667, filed on Sep. 30, 2013.

(51) Int. Cl. H01L 23/40; H01L 23/367; H01L 21/48

(52) U.S. Cl. CPC H01L 23/4093; H01L 23/40; H01L 21/4882; H01L 23/3672

(57) ABSTRACT

An assembly for engaging a heat sink with an electrical component heat source includes a first retaining device with a frame that defines an opening to receive at least a portion of the heat sink and/or the heat source. The frame may be assembled with a heat sink and a retainer element arranged to resiliently bias the heat sink into contact with the heat source, and thereafter the heat sink assembly may be engaged with a heat source. A contact plate of the heat sink may be positioned into the opening of the frame from a top of the frame, i.e., inserted in a top-down direction, and the frame may be arranged for engagement with a tool to mount the fully assembled heat sink, frame and retainer element combination to the heat source.

### CROSS REFERENCE TO RELATED APPLICATION

This application is a continuation of PCT/CN2013/084667, filed Sep. 30, 2013, which is hereby incorporated by reference in its entirety.

### BACKGROUND

1. Field of Invention

Aspects of the invention relate to a heat sink assembly, e.g., for holding parts together used in transferring heat from an electronic component heat source, such as an integrated circuit or other electronic component, to a heat sink.

2. Related Art

Heat sink assemblies are widely used to dissipate or otherwise transfer heat from an electronic component, such as an integrated circuit, computer processor, printed circuit board, or other electronic component. Proper cooling of electronic components, particularly computer-related components, can be important for a variety of well-known reasons, such as preventing damage to components due to overheating, maintaining suitably high processing speed or other circuit component operation, and so on. U.S. Patent Application Publications 2010/0200206 and 2010/0018670 describe various embodiments of heat sink assemblies used to cool electronic components.

### SUMMARY OF INVENTION

In some aspects of the invention, a first retaining device used to hold a heat sink (such as a finned metal block) and heat source (such as a computer processor) together may include a frame that defines an opening to receive at least a portion of the heat sink and/or the heat source. The frame may be arranged to be fully assembled with the heat sink and a retainer element (which is arranged to bias the heat sink into contact with the heat source), and be capable of engagement with the heat source in the fully assembled condition. Moreover, after the full assembly is engaged with the heat source, the frame may allow for partial disassembly, if needed. For example, the frame may remain engaged with the heat source while the heat sink is removed and exchanged for another heat sink, or a thermal coupling is verified, if desired. In some embodiments, the heat sink may be larger than the frame in at least one dimension, but not interfere with engagement of the fully assembled heat sink, frame and retainer element arrangement with the heat source. These features may provide significant advantages, such as allowing a manufacturer the ability to fully assemble a heat sink, frame and retainer element ready for engagement with a heat source, and then engage the completed assembly with the heat source. This can help reduce the likelihood that improper components are assembled together. After engagement with the heat source, if there is some need to verify the engagement, check a solder connection at the heat source, change the heat sink, etc., this can be easily done, since the frame may remain engaged with the heat source while the retainer element is removed and the heat sink disengaged from the heat source and removed from the frame as needed.

In one aspect of the invention, a heat sink assembly includes a heat sink having a base with a contact plate. The heat sink may include other heat dissipating or heat transferring features, such as one or more fins extending from the base, a channel for conducting cooling liquid, one or more heat pipes thermally coupled to the contact plate, etc. A portion of the contact plate may be arranged to contact and receive heat from a heat source, e.g., a thermal grease may help to conductively couple a portion of the contact plate with the heat source to receive heat. A frame used to engage the heat sink with the heat source may have four sides defining an opening in which the portion of the contact plate of the heat sink is received. Two of the frame sides that are opposed to each other may include one or more holding features, such as inwardly extending tabs or protrusions, to engage with the heat source and secure the frame to the heat source. In one embodiment, the tabs may engage the heat source in a space between a ball grid array substrate and a circuit board that is joined to the ball grid array substrate by an array of solder balls, although other engagement arrangements are possible. The two opposed sides may each include a feature to engage with a tool used to flex the two sides so as to move the one or more holding features on the two opposed sides away from each other. For example, the two opposed sides may include one or more slots formed in a top of the frame side that can receive a tool used to flex the frame. The frame may be flexed so as to move the heat source-engaging tabs away from each other so a portion of the heat source can be received into the opening of the frame. Upon release of the flexing force, the frame may return to its undeformed shape, causing the tabs to engage the heat source. A top of the four sides of the frame may define a flat, continuous surface around the frame, and a bottom of the four sides may define a discontinuous surface around the frame, e.g., one or more legs or other features may extend downwardly from a bottom of the frame and contact the heat source. A retainer element may be arranged to engage the frame and heat sink with the portion of the contact plate received in the opening to urge the heat sink to move downwardly relative to the frame. For example, the retainer element may include a spring plate or wire arranged to resiliently bias the heat sink to move into the frame opening so that the heat sink is biased into contact with an engaged heat source.

The frame may be arranged to receive the portion of the contact plate in a direction from a top of the opening to a bottom of the opening, i.e., in a top-down direction, and the heat sink, frame and retainer element may be arranged for assembly together with the portion of the contact plate received in the opening of the frame and the retainer element engaged with the frame such that the assembled heat sink, frame and retainer element are engagable with a heat source. That is, the fully assembled heat sink, frame and retainer element may be engaged together to a heat source in a single operation. Since the contact plate of the heat sink is received into the frame opening in a top-down direction, the heat sink is removable from the frame even while the frame is engaged with a heat source. This allows for disassembly if needed, but also accommodates heat sink base sizes that are larger than the frame.

In one embodiment, the base of the heat sink may have a size that is larger than a size of the opening, e.g., the base of the heat sink may have a width, area or other dimension that is larger than a width, area or other dimension of the opening. In other embodiments, the heat sink may include fins, heat pipes or other features that extend laterally over one or more of the frame sides. This feature allows for a relatively large heat sink, but does not interfere with proper engagement of a fully assembled heat sink, frame and retainer element assembly with a heat source.

In one embodiment, the one or more holding features (e.g., tabs, protrusions, holes, grooves, etc.) are formed at a bottom end of a corresponding side of the frame, e.g., so that the opposed sides can be flexed to move the bottom ends of the opposed sides away from each other. If the frame includes one or more legs on its bottom, the legs may be arranged on sides of the frame that are adjacent to sides that include one or more holding features. Thus, for example, when the frame is placed onto the heat source during assembly and the sides are flexed to receive the heat source, the legs may contact the heat source so that when the sides are released, the holding features may be properly located to engage with corresponding holes, slots, tabs, etc., of the heat source.

In another aspect of the invention, a method for assembling a heat sink and an electrical component heat source includes providing a frame defining an opening and arranged to engage with a heat source and resist movement of the heat source relative to the frame in a z direction. The frame may also engage the heat source to resist movement of the heat source relative to the frame in x and/or y directions as well. The frame may be assembled with a heat sink by moving a contact plate of the heat sink into the opening of the frame in a top-down direction and engaging a retainer element with the frame to bias the heat sink to move into the opening. Thereafter, the opening defined by the frame may be enlarged by engaging opposed sides of the frame with a tool to receive a portion of a heat source while the frame, heat sink and retainer element are assembled together. With a portion of the heat source received in the enlarged portion of the opening, a size of the opening may be reduced to engage the frame with a portion of the heat source in the opening while the frame, heat sink and retainer element are assembled. Engagement of the frame with the portion of the heat source may cause the retainer element to resiliently bias the heat sink contact plate into thermal contact with a portion of the heat source, e.g., to press downwardly on the heat sink with a spring force to urge the heat sink into contact with the heat source.

As with the embodiments above, a base of the heat sink may have a size that is larger than a size of the opening. For example, the base of the heat sink may have a width that is larger than a width of the opening, yet still not interfere with mounting of the fully assembled assembly on the heat source. The opening of the frame may be enlarged by engaging a slot formed in a sidewall of the frame with a tool that is used to flex opposed sides of the frame so as to move holding features on the opposed sides away from each other.

These and other aspects of the invention will be apparent from the following description and claims.

### BRIEF DESCRIPTION OF THE DRAWINGS

Aspects of the invention are described below with reference to the following drawings in which like numerals reference like elements, and wherein:

FIG. 1 shows an exploded view of an embodiment of a heat sink assembly in engagement with a heat source in accordance with aspects of the invention;

FIG. 2 is a cross-sectional view of the FIG. 1 embodiment in an assembled condition with a heat source;

FIG. 3 shows an exploded view of an embodiment of a heat sink assembly having an alternate retainer element configuration;

FIG. 4 shows a bottom view of the assembled embodiment of FIG. 3;

FIG. 5 shows a side view of the assembled embodiment of FIG. 3;

FIG. 6 shows a cross sectional view along the line 6-6 of FIG. 5;

FIG. 7 shows an alternate retainer element configuration in an illustrative embodiment;

FIG. 8 shows a side view of a heat sink assembly employing the retainer element of FIG. 7;

FIG. 9 shows an alternate retainer element configuration in an illustrative embodiment;

FIG. 10 shows a side view of a heat sink assembly employing the retainer element of FIG. 9;

FIG. 11 shows an exploded view of an embodiment of a heat sink assembly having yet another retainer element configuration;

FIG. 12 shows an alternate retainer element configuration for use with the FIG. 11 embodiment; and

FIG. 13 shows a cross sectional view of the heat sink assembly of FIG. 11 along the line 13-13.

### DETAILED DESCRIPTION

It should be understood that aspects of the invention are described herein with reference to certain illustrative embodiments and the figures. The illustrative embodiments described herein are not necessarily intended to show all aspects of the invention, but rather are used to describe a few illustrative embodiments. Thus, aspects of the invention are not intended to be construed narrowly in view of the illustrative embodiments. In addition, it should be understood that aspects of the invention may be used alone or in any suitable combination with other aspects of the invention.

As discussed above, an embodiment of the invention includes a frame arranged to engage with a portion of a heat source, such as an integrated circuit, computer processor, ball grid array substrate, a printed circuit board, or other component, such that portions of the frame at least partially surround a part of the heat source. For example, the frame may have sides that define an opening and which can be elastically deformed, flexed or otherwise moved to enlarge a size of the opening defined by the frame, e.g., so that a portion of the heat source can be received into the opening. Once a portion of the heat source is received in the opening, the sides may be released, allowing the frame to return to its unflexed shape to engage the heat source and restrict the frame's movement relative to the heat source in x and/or y directions (which may be in a plane of the frame). The frame may also engage the heat source to restrict its movement in the z direction, e.g., so that the frame cannot move beyond a certain point in an upward direction relative to the heat source (which may be perpendicular to a plane of the frame).

The frame may receive a portion of a heat sink into the opening in a top-down direction, i.e., such that the heat sink portion is moved into the opening in a direction from a top of the frame toward the bottom. As a result, the heat sink may be larger than the frame, yet still be received into the frame opening. Moreover, the frame and heat sink may be made so that with the heat sink portion received into the opening, and a retainer element engaged with the frame to hold the heat sink in place, the fully assembled construction may be engaged with a heat source. Once the frame is engaged with the heat source, the retainer element engages with the frame and contacts the heat sink to bias the heat sink toward a heat source engaged by the frame. For example, the retainer element may apply a resilient bias on the heat sink in a downward direction toward the heat source. Since the frame may be restricted in upward movement relative to the heat source, the resilient bias on the heat sink may bias the heat source and heat sink together.

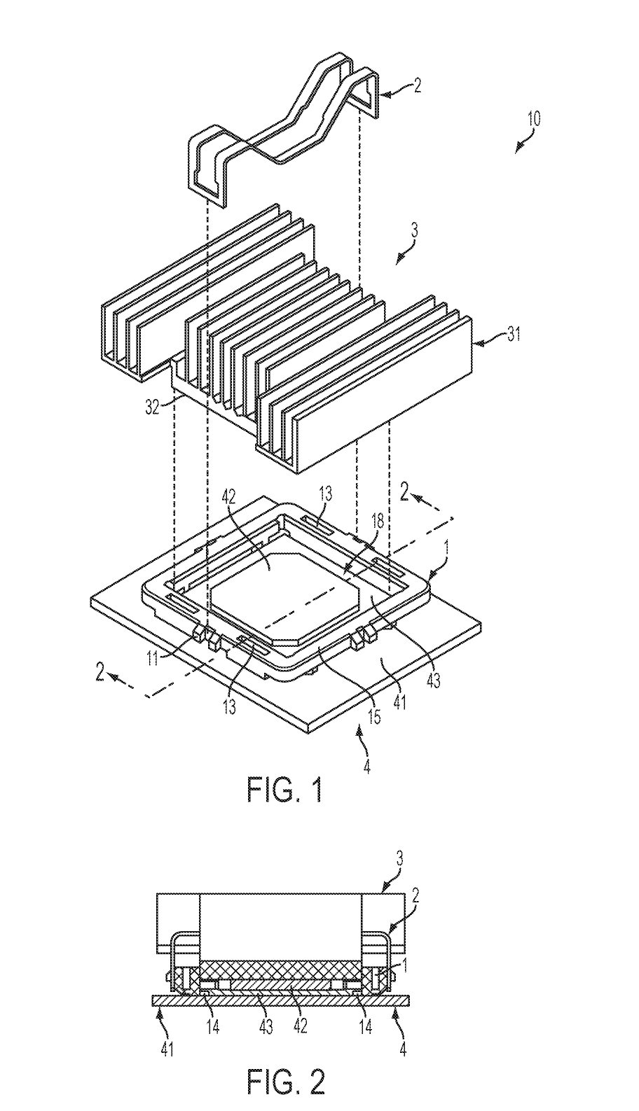

FIG. 1 shows an illustrative embodiment of a heat sink assembly 10 that includes a heat source 4, a heat sink 3, and first and second retaining devices 1, 2 that hold the heat source 4 and heat sink 2 in thermal contact with each other. While the heat source 4 may include any suitable component or components, in this illustrative embodiment the heat source 4 includes a printed circuit board (PCB) 41, a ball grid array support 43 and an integrated circuit 42. Other components may be additionally or alternately included, such as a thermal interface material, such as a thermally conductive grease or oil to help with thermal transfer between the heat source 4 and the heat sink 3. It should be noted that a heat source 4 that interacts with the first and second retaining devices 1, 2 need not necessarily be capable of itself generating heat, but instead may function to transfer heat from a heat generating component or other heat source to a heat sink. For example, the heat source 4 may include a heat pipe that is in thermal contact with an integrated circuit which generates heat, and transfers that heat to the heat pipe. The heat pipe may, in turn, transfer heat to the heat sink 3.

The heat sink 3 in this illustrative embodiment includes a base with a contact plate 32 and a plurality of fins 31 that extend upwardly from the base. A lower surface of the contact plate 32 is arranged to make thermal contact with, or otherwise thermally communicate with an upper surface of the integrated circuit 42 so as to receive heat from the integrated circuit 42 and dissipate the heat via the fins 31. Of course, it should be understood that the heat sink 3 may include any suitable additional or alternate components, such as one or more heat pipes that are thermally coupled to the contact plate 32 or other collector block, a thermoelectric cooling device, a phase-change based or other thermal transfer medium, a liquid-based heat exchanger (e.g., including a channel in the contact plate 32 that carries a circulating liquid used to carry heat from the heat sink 3), and so on. In short, the heat sink 3 may include any suitable component to receive and transfer heat away from a heat source 4. The heat sink 3 in this embodiment may be formed in any suitable way, such as by casting, extruding, machining, forging, welding, or otherwise assembling portions made of any suitable material, such as conductive metals (aluminum, copper, steel, etc.), plastics, composites and/or combinations of any such materials.

The first retaining device 1 in this illustrative embodiment includes a frame clip with four sidewalls 15 that define an opening 18 arranged to receive a portion of the heat source 4 and the contact plate 32 of the heat sink 3. In one embodiment, the integrated circuit 42 and ball grid array substrate 43 may be received into the opening 18, and the sidewalls 15 may engage with edges of the ball grid array substrate 43 (e.g., by clamping, by engaging one or more tabs, grooves, hooks, teeth, wedges, barbs, or other holding features 14 with the substrate 43, etc.) to resist movement of the frame clip 1 relative to the heat source 4 in x and/or y directions as well as the z direction. (As can be seen in FIG. 1, the x and y directions may be directions in a plane of the frame clip 1 and/or the opening 18, and the z direction may be perpendicular to the plane of the opening 18.) This is not to say that in all embodiments the frame clip 1 is made incapable of any movement in x and/or y directions relative to the heat source 4, but rather the first retaining device 1 may be restrained in movement so as to prevent disengagement of the first retaining device 1 from the heat source 4 (absent forces that would deform or damage the heat source 4 and/or first retaining device 1). Thus, in some embodiments, the first retaining device 1 may be somewhat moveable in x and/or y directions relative to the heat source 4, but when suitably engaged with the heat source 4, may not be movable so as to disengage from the heat source 4.

In this embodiment, and as can be seen in FIG. 2, two opposed sidewalls 15 each include one or more tabs 14 or other holding features that extend inwardly from the lower end of the sidewall 15 and engage the ball grid array substrate 43 (or other heat generating component portion) to hold the frame clip 1 in place, particularly in the z direction. The second retainer element 2, which may be a spring clip or other retainer element, may engage the frame clip 1 and contact the heat sink 3 so that the heat sink 3 is biased to move downwardly, in the z direction, relative to the frame clip 1 in the opening 18. This may bias the heat sink 3 contact plate 32 into contact with the heat source 4, helping to transfer heat at the interface by conduction. The retainer element 2 may engage one or more engagement features 11 on the frame clip 1, such as one or more tabs, protrusions, holes, or other, and/or may engage with a surface (such as an underside) of the frame clip 1.

In accordance with an aspect of the invention, the frame clip, the heat sink and the retainer element may be completely assembled together and then attached to a heat source in the assembled condition. This feature may provide advantages, such as ensuring that the proper clip, heat sink and retainer element are used together with the corresponding heat source. For example, heat sink assemblies with associated frame clip and retainer element may be pre-assembled and packaged ready for attachment to a particular type of heat source. This way, a user can be ensured that the proper parts are associated with each other and are fully ready for attachment to a heat source, without any need to verify anything other than that the assembly as a whole is properly associated with the heat source. This is contrast to many heat sink assemblies that include frame clips which cannot be attached to a heat source while assembled with a heat sink and retainer.

In another aspect of the invention, the frame clip 1 includes a tool-engaging feature arranged to engage with a tool used to flex or bend the opposing sidewalls so as to spread tabs or other engagement features from each other to allow a portion of a heat source to be received in the opening 18 and engaged by the engagement features. In the embodiment of FIG. 1, the opposed sidewalls 15 that includes tabs 14 to engage the heat source 4 also include slots 13 to receive a tool (not shown), which can bend the sidewalls 15 to move the tabs 14 away from each other. The tool may take various forms, such as an L-shaped bar having a short end which is received into a slot 13, and a lever arm which can be moved to flex the sidewalls 15. The frame clip 1 may be made of a resilient and/or elastically deformable material, such as a molded plastic or metal, that allows opposed sides of the frame 1 to be twisted or flexed relative to each other, but will resume its unflexed shape when the flexing force is removed. Alternately, the frame clip 1 may include one or more resilient or elastically deformable portions that permit suitable movement of the holding features 14 relative to each other so the frame clip 1 can be engaged/disengaged with respect to a heat source 4. Accordingly, the frame clip 1 may be made of any suitable material, such as plastics, metals, composites and/or combinations of materials, and in any suitable way, such as by machining, molding, casting, forging, sintering, stereo lithography, 3D printing, etc.

In accordance with another aspect of the invention, the heat sink assembly may be attached to a heat source while fully assembled, even though the heat sink has a size which is larger than the frame clip opening. For example, as can be seen in FIG. 1, the heat sink 3 overhangs the frame clip 1 on two sides. However, the heat sink 3 is arranged so that the slots 13 are exposed to receive a mounting tool and so that the sidewalls 15 of the frame clip 1 can be flexed to engage the heat source 4. This arrangement allows for a relatively large heat sink base (e.g., which may provide improved cooling characteristics) that is larger than the frame clip, yet still allows for fully assembled mounting of the heat sink, frame clip and retainer element on a heat source. So, for example, the heat sink 3 may be larger in the x or y (or possibly x and y) direction than the frame clip 1, yet still allow for fully assembled mounting of the heat sink assembly. In one embodiment, the heat sink 3 may include windows, notches or other openings that allow a user to engage a slot 13 or other tool-engaging feature of the frame clip 1 to permit attachment to a heat source 4, while the heat sink 3 may otherwise overhang the frame clip at all of the sidewalls 15 of the frame clip 1. Said another way, the heat sink 3 may have a base with an area in the x-y plane that is larger than the area of the opening 18, and yet the assembly may be arranged to provide for fully assembled attachment to a heat source.

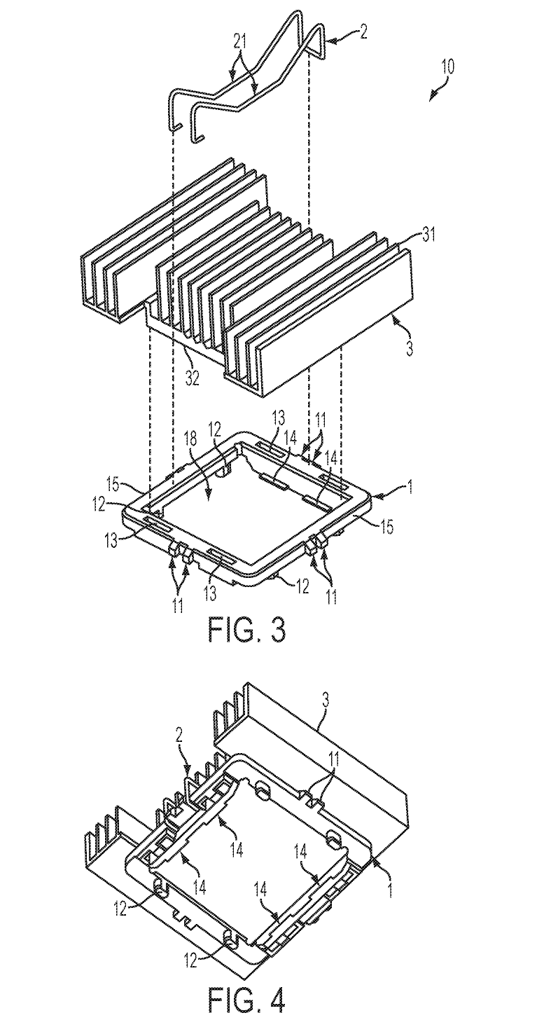

Another aspect of the invention is that the heat sink and frame clip are arranged such that the contact plate 32 of the heat sink 3 can be received into the opening 18 of the frame clip 1 in a top-down direction, i.e., in a direction along the z axis from a top of the frame clip 1 towards a bottom of the frame clip 1. Such an arrangement allows for simpler frame clip construction, and also helps avoid potential mechanical interference between the frame clip 1 and the heat sink 3. Moreover, assembly of the heat sink, frame clip and retainer element is made easier, e.g., because the assembly can be made by placing the frame clip on a surface, placing the heat sink over the frame clip with the contact plate in the opening 18, and then engaging the retainer element with the frame clip. There is no need to specifically align features of the heat sink and frame clip, other than positioning the contact plate in the opening. This is in contrast to many other arrangements in which the frame clip includes structures that extend into the opening 18 and interfere with the heat sink, requiring specific alignment of the heat sink and frame clip for assembly and/or requiring the heat sink to be inserted into the opening from the bottom of the frame clip. FIG. 3 shows an exploded view of a heat sink assembly 10 and illustrates that the assembly may be formed by placing the contact plate 32 of the heat sink 3 into the opening 18 in a top-down direction and then attaching the retainer element 2 to the frame clip 1. This embodiment has a different retainer element 2 arrangement than FIG. 1, but otherwise is identical. Note, therefore that various changes may be made to different parts of a heat sink assembly 10. In this embodiment, the retainer element 2 is formed of a wire, rather than as a stamped piece of sheet or flat spring as in FIG. 1. In either case, however, the retainer element 2 operates in the same way, i.e., end portions of the retainer element 2 engage the frame clip 1, and a center portion 21 of the retainer element contacts the heat sink 3 to bias the heat sink to move downwardly relative to the frame clip 1.

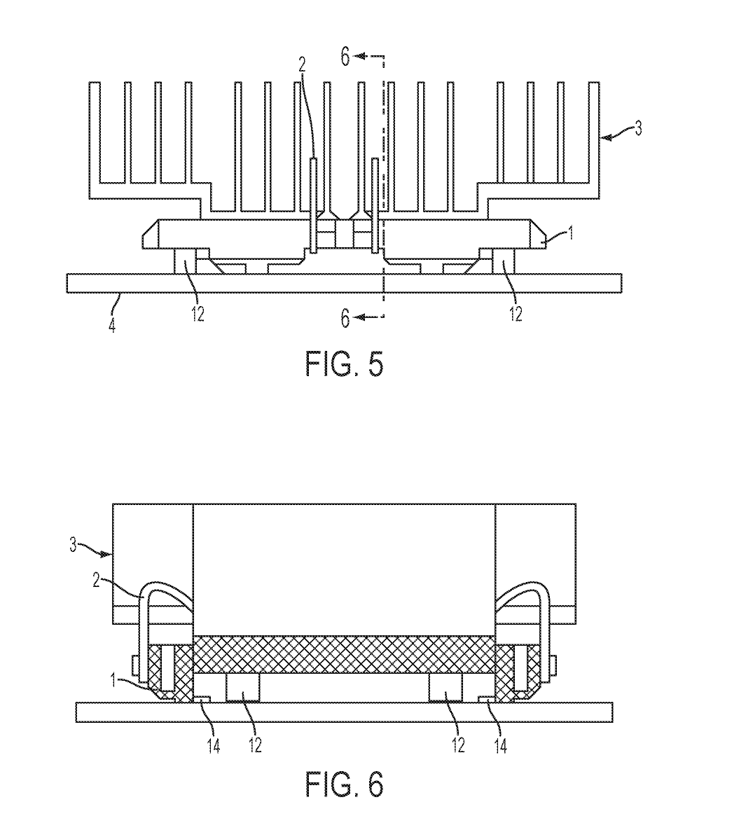

Another aspect of the invention is that the frame clip may have a flat, continuous surface on a top face, and a discontinuous surface on the bottom face. The top face of the frame clip 1 can be seen in FIG. 3, and is interrupted only by the slots 13. In contrast, the bottom face of the frame clip 1 includes four legs 12 which extend downwardly, along with portions of the sidewalls 15 that include the tabs 14 for engaging the heat source 4, as can be seen in FIG. 4. Such an arrangement may make the frame clip 1 more compliant and accommodating of variations in an upper surface of a heat source 4. That is, since the frame clip 1 may only contact the heat source 4 at lower ends of the legs 12 (as can be seen in FIG. 5), variations in height at other areas of the heat source 4 will have no effect on the frame clip 1 engaging the heat source 4. Also, the frame clip 1 may be more easily manufactured to closely control the relative heights of the legs 12 and the tabs 14, thereby arranging the frame clip 1 to suitably engage the heat source 4. For example, the frame clip 1 may be arranged such that with the sides 15 having the tabs 14 flexed apart, the legs 12 contact the heat source 4 so that the tabs 14 are properly positioned to engage the heat source 4 once the flexing force on the frame clip 1 is released. This may make engagement of the assembly 10 with the heat source 4 easier, since the legs 12 may ensure proper alignment of the tabs 14 with corresponding grooves or other features of the heat source 4. Openings provided between the legs 12 (as can be seen in FIG. 6) may also permit airflow at the heat source 4, helping to cool the heat source 4. In this embodiment, the legs 12 are arranged at sidewalls 15 that are opposed to each other and are adjacent to the sidewalls 15 that include the tabs 14, but could be located in other places.

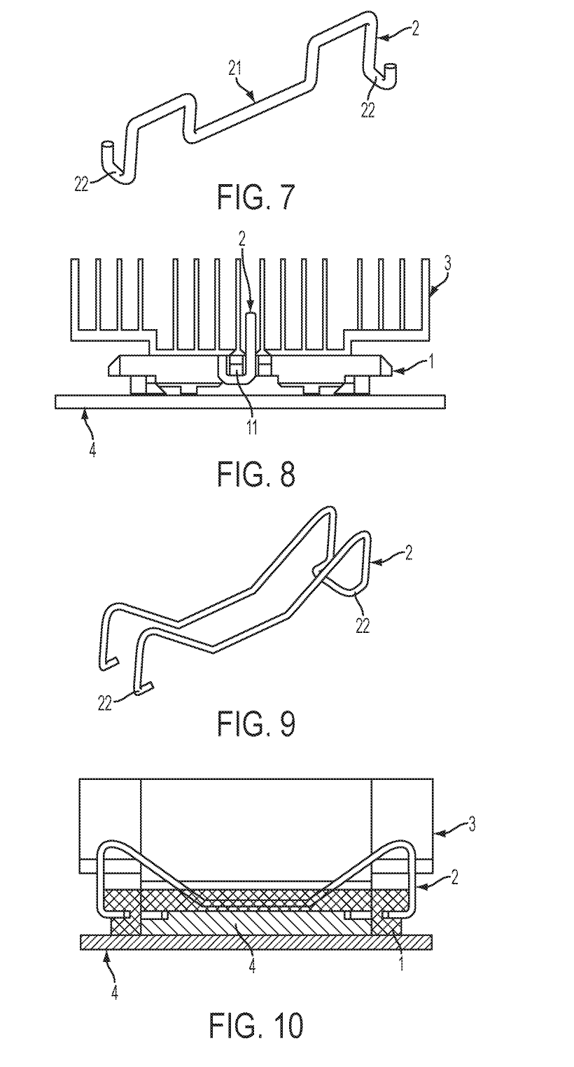

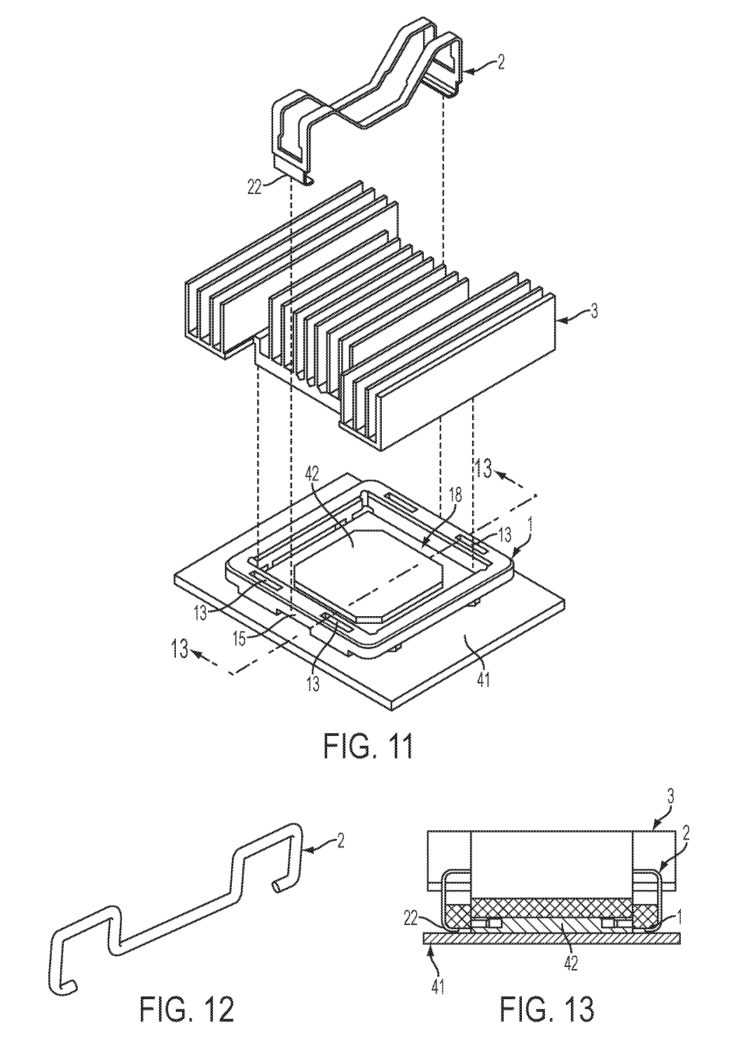

As noted above, embodiments of the invention are not limited to any particular arrangement for the portions of the heat sink assembly 10. For example, FIGS. 7 and 9 show an alternate retainer element arrangement that can be used. As can be seen in the assembled view of FIG. 8, the end portions 22 of the retainer element 2 of FIG. 7 may engage with opposed tabs 11 on the frame 1 by hooking underneath and around the tabs 11. As can be seen in FIG. 10, the end portions 22 of the retainer element 2 of FIG. 9 can fit into horizontal slots or holes in the frame clip sidewall 15. Of course, the retainer element 2 need not engage with a hole, tab or other feature of the frame clip 1, but instead may simply contact an outer surface of the frame clip 1. For example, FIG. 11 shows an arrangement in which distal ends of the retainer element 2 can contact a bottom surface of the frame clip 1, as can be seen in FIG. 13. As with other examples, the retainer element 2 may be formed of a bent wire, as shown in FIG. 12, rather than a stamped sheet as in FIG. 11, and yet still function in the same way to engage the frame clip 1.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A heat sink assembly including:
a heat sink having a base with a contact plate, a portion of the contact plate being arranged to contact and receive heat from a heat source;
a frame having four sides defining an opening in which the portion of the contact plate of the heat sink is received, two of the sides that are opposed to each other including one or more holding features to engage with a heat source to secure the frame to the heat source, the two opposed sides each including a feature to engage with a tool to flex the two sides so as to move the one or more holding features on the two opposed sides away from each other, a top of the four sides defining a flat, continuous surface around the frame, and a bottom of the four sides defining a discontinuous surface around the frame; and
a retainer element arranged to engage the frame and heat sink with the portion of the contact plate received in the opening to urge the heat sink to move downwardly relative to the frame,
wherein the frame is arranged to receive the portion of the contact plate in a direction from a top of the opening to a bottom of the opening, and the heat sink, frame and retainer element are arranged for assembly together with the portion of the contact plate received in the opening of the frame and the retainer element engaged with the frame such that the assembled heat sink, frame and retainer element are engagable with a heat source.

2. The assembly of claim 1, wherein the base of the heat sink has a size that is larger than a size of the opening.

3. The assembly of claim 2, wherein the base of the heat sink has a width that is larger than a width of the opening.

4. The assembly of claim 1, wherein the tool engaging features include a slot formed in a sidewall of the frame.

5. The assembly of claim 1, wherein the one or more holding features are formed at a bottom end of a corresponding side of the frame.

6. The assembly of claim 1, wherein the bottom of the frame includes one or more legs that extend downwardly and define, in part, the discontinuous surface.

7. The assembly of claim 6, wherein the one or more legs are arranged on sides of the frame that are adjacent to sides that include one or more holding features.

8. The assembly of claim 1, wherein the retainer element is arranged to apply a resilient bias to the heat sink to urge the heat sink into contact with a heat source engaged by the frame.

9. The assembly of claim 1, wherein the one or more holding features to engage with a heat source received in the opening include one or more tabs that extend inwardly from a respective side of the frame.

10. The assembly of claim 9, wherein the one or more holding features includes one or more tabs arranged to engage with a heat source in a space between a ball grid array substrate and a circuit board that is joined to the ball grid array substrate by an array of solder balls.

11. The assembly of claim 1, wherein the frame is arranged to engage the heat sink with a heat source that includes a ball grid array, a computer processing chip and/or a printed circuit board.

12. A method for assembling a heat sink and an electrical component heat source, comprising:
providing a frame defining an opening and arranged to engage with a heat source and resist movement of the heat source relative to the frame in a z direction;
assembling the frame with a heat sink by moving a contact plate of the heat sink into the opening of the frame in a top-down direction and engaging a retainer element with the frame to bias the heat sink to move into the opening;
enlarging the opening defined by the frame by engaging opposed sides of the frame with a tool to receive a portion of a heat source while the frame, heat sink and retainer element are assembled together; and
reducing a size of the opening to engage the frame with a portion of the heat source in the opening while the frame, heat sink and retainer element are assembled, engagement of the frame with the portion of the heat source causing the retainer element to resiliently bias the heat sink contact plate into thermal contact with a portion of the heat source.

13. The method of claim 12, wherein the base of the heat sink has a size that is larger than a size of the opening.

14. The method of claim 13, wherein the base of the heat sink has a width that is larger than a width of the opening.

15. The method of claim 12, wherein the step of enlarging includes engaging a slot formed in a sidewall of the frame with the tool.

16. The method of claim 12, wherein the step of reducing the size includes engaging one or more holding features formed at a bottom end of a corresponding side of the frame with the heat source.

17. The method of claim 16, wherein the one or more holding features includes one or more tabs arranged to engage with a heat source in a space between a ball grid array substrate and a circuit board that is joined to the ball grid array substrate by an array of solder balls.

18. The method of claim 12, wherein a bottom of the frame includes one or more legs that extend downwardly and define, in part, a discontinuous surface at the bottom of the frame.
